(19) United States
(12) Patent Application Publication
(10) Pub. No.: US 2026/0068472 A1
(43) Pub. Date: Mar. 5, 2026

(54) PIXEL STRUCTURE,DISPLAY PANEL, AND DISPLAY DEVICE

(71) Applicant: HKC CORPORATION LIMITED, SHENZHEN (CN)

(72) Inventors: Tingting YANG, SHENZHEN (CN); Jun SHI, SHENZHEN (CN); Dongmei WEI, SHENZHEN (CN); Ke LI, SHENZHEN (CN); Lidan YE, SHENZHEN (CN)

(73) Assignee: HKC CORPORATION LIMITED, SHENZHEN (CN)

(21) Appl. No.: 19/302,001

(22) Filed: Aug. 17, 2025

(30) Foreign Application Priority Data
Aug. 30, 2024 (CN) 202411218248.5

(51) Int. Cl. H10K 59/35; H10K 59/80; H10K 102/10

(52) U.S. Cl. CPC H10K 59/353; H10K 59/878; H10K 59/879; H10K 2102/10

(57) ABSTRACT

A pixel structure, a display panel, and a display device. The pixel structure includes multiple subpixel units, multiple reflective layers, a refractive component, and a control component; the multiple subpixel units and multiple reflective layers are arranged in a ring-shaped configuration, and the refractive component includes a first refractive layer, a second refractive layer, and a third refractive layer stacked in sequence. The second refractive layer is overlapped with the subpixel units, while the first refractive layer and the third refractive layer are misaligned with the subpixel units, such that light from the subpixel units is directed only into the second refractive layer. The control component is configured to adjust the refractive index of the second refractive layer, causing light within the second refractive layer to undergo total internal reflection or to exit from at least one of the first refractive layer and the third refractive layer.

### CROSS-REFERENCE TO RELATED APPLICATIONS

The present application claims priority of Chinese Patent Application No. 202411218248.5, filed on Aug. 30, 2024, the entire contents of which are hereby incorporated by reference in their entirety.

### TECHNICAL FIELD

The present disclosure relates to the field of display technologies, and in particular to a pixel structure, a display panel, and a display device.

### BACKGROUND

With the advancement of transparent display technologies, transparent display devices have gradually permeated daily life. For instance, in certain regions, transparent window screens have been implemented in trains to display real-time daily information such as weather forecasts, news, train operational status, and location data. Beyond transportation, transparent Organic Light-Emitting Diode (OLED) displays can be further utilized in architectural design, commercial advertising, office environments, and other applications.

Currently, achieving transparency in OLED panels primarily relies on transparent electrodes, the self-luminous properties of OLEDs, and the incorporation of transparent subpixels distributed systematically across the display region. However, the limited light transmittance of transparent subpixels constrains further enhancements in transparency. Furthermore, such displays lack the ability to freely toggle between transparent and non-transparent modes.

### SUMMARY OF THE DISCLOSURE

A pixel structure, including:
a plurality of subpixel units and a plurality of reflective layers; wherein the plurality of subpixel units and the plurality of reflective layers enclose to form a ring-shaped configuration; and
a refractive component and a control component, that are disposed within the ring-shaped configuration;
wherein the refractive component includes a first refractive layer, a second refractive layer, and a third refractive layer stacked in sequence; in a direction parallel to a plane in which the ring-shaped configuration is located, the second refractive layer is overlapped with a light-emitting layer of the subpixel unit, and the first refractive layer and the third refractive layer are misaligned with the light-emitting layer of the subpixel unit; light incident from the subpixel unit is configured to only enter the second refractive layer;
wherein the control component is configured to adjust a refractive index of the second refractive layer; in response to adjustment of the refractive index of the second refractive layer, the light incident from the subpixel unit into the second refractive layer is capable of switching between undergoing total internal reflection within the second refractive layer and being emitted from at least one of the first refractive layer and the second refractive layer.

A display panel, including a drive substrate and a plurality of the pixel structures as above disposed on the drive substrate;
wherein the plurality of pixel structures are distributed according to a predetermined pattern; for each adjacent two pixel structures among the plurality of pixel structures, the adjacent two pixel structures are a first pixel structure and a second pixel structure, a side of the first pixel structure is close to a side of the second pixel structure, and a corresponding subpixel unit on the side of the first pixel structure is adjacent to a corresponding reflective layer of the second pixel structure; the light incident from each subpixel unit is configured to be reflected back into a corresponding pixel structure.

A pixel structure, including:
a plurality of subpixel units and a plurality of reflective layers; wherein the plurality of subpixel units and the plurality of reflective layers enclose to form a ring-shaped configuration; and
a refractive component, disposed within the ring-shaped configuration;
wherein the pixel structure is configured to be spliced with another pixel structure, and the other pixel structure has a same structure as the pixel structure; in a spliced state, the pixel structure shares a common side with the other pixel structure, where a corresponding subpixel unit of the pixel structure is attached to a corresponding reflective layer of the other pixel structure, or a corresponding subpixel unit of the other pixel structure is attached to a corresponding reflective layer of the pixel structure;
wherein the refractive component includes a first refractive layer, a second refractive layer, and a third refractive layer stacked in sequence; in a direction parallel to a plane in which the ring-shaped configuration is located, the second refractive layer is overlapped with a light-emitting layer of the subpixel unit, and the first refractive layer and the third refractive layer are misaligned with the light-emitting layer of the subpixel unit; light incident from the subpixel unit is configured to only enter the second refractive layer;
wherein in response to a refractive index of the second refractive layer being changed, the pixel structure is configured to switch between a first display mode and a second display mode;
in the first display mode, the light in the second refractive layer is caused to undergo total internal reflection within the second refractive layer and be emitted from neither of the first refractive layer and the third refractive layer;
in the second display mode, the light in the second refractive layer is caused to be emitted from at least one of the first refractive layer and the third refractive layer.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a plane structural schematic view of a display panel according to Implementation 1 of the present disclosure.

FIG. 2 is a plane structural schematic view of a pixel structure according to Implementation 1 of the present disclosure.

FIG. 3 is a cross-sectional structural schematic view of a pixel structure as shown in FIG. 1 along line A-A according to some embodiments of the present disclosure.

FIG. 4 is a schematic view illustrating a state where the pixel structure as shown in FIG. 3 is in a pixel region display mode.

FIG. 5 is a schematic view illustrating a state where the pixel structure as shown in FIG. 3 is in a transparent display mode.

FIG. 6 is a cross-sectional structural schematic view of a pixel structure as shown in FIG. 1 along line A-A according to other embodiments of the present disclosure.

FIG. 7 is a schematic view illustrating a state where the pixel structure as shown in FIG. 6 is in a pixel region display mode.

FIG. 8 is a schematic view illustrating a state where the pixel structure as shown in FIG. 6 is in a first display mode.

FIG. 9 is a schematic view illustrating a state where the pixel structure as shown in FIG. 6 is in a second display mode.

FIG. 10 is a schematic view illustrating a state where the pixel structure as shown in FIG. 6 is in a transparent display mode.

FIG. 11 is a plane structural schematic view of a display panel according to Implementation 2 of the present disclosure.

FIG. 12 is a plane structural schematic view of a display panel according to Implementation 3 of the present disclosure.

FIG. 13 is a plane structural schematic view of a display panel according to Implementation 4 of the present disclosure.

FIG. 14 is a structural schematic view of a display device according to some embodiments of the present disclosure.

FIG. 15 is a cross-sectional structural schematic view of a pixel structure as shown in FIG. 1 along line A-A according to further other embodiments of the present disclosure.

### DETAILED DESCRIPTION

The following description, in conjunction with the accompanying drawings, provides a detailed explanation of the technical solutions of the embodiments of the present disclosure.

In the following description, specific details such as specific system structures, interfaces, and technologies are provided for the purpose of explanation rather than limitation, in order to facilitate a thorough understanding of the present disclosure.

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first.” “second.” and “third” used in the present disclosure are for descriptive purposes only and should not be understood as indicating or implying relative importance or the number of technical features indicated. Therefore, features defined with “first.” “second.” or “third” may explicitly or implicitly include at least one of the features indicated. In the description of the present disclosure. “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have.” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

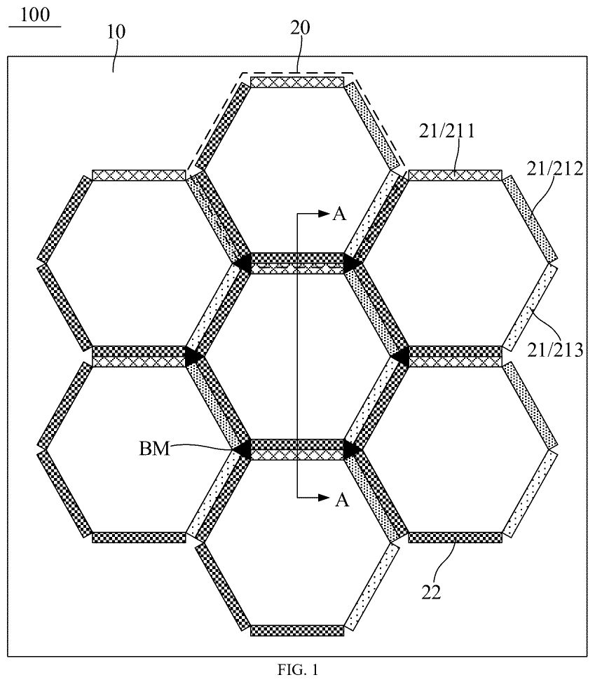

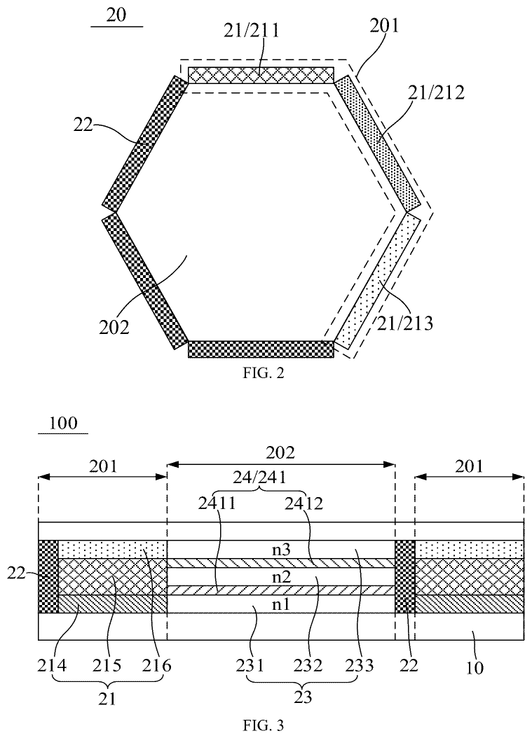

Referring to FIGS. 1 and 2, FIG. 1 is a plane structural schematic view of a display panel according to Implementation 1 of the present disclosure, and FIG. 2 is a plane structural schematic view of a pixel structure according to Implementation 1 of the present disclosure. In the embodiments, a display panel 100 is provided, which includes a drive substrate 10 and multiple pixel structures 20 disposed on the drive substrate 10. The multiple pixel structures 20 are distributed according to a predetermined pattern.

The drive substrate 10 includes multiple subpixel drive circuits, which are each electrically connected to a corresponding subpixel unit 21 in a corresponding pixel structure 20, and configured to drive the corresponding subpixel unit 21 to emit light, thereby achieving the display function. Specifically, each pixel structure 20 includes multiple subpixel units 21 and multiple reflective layers 22, with the multiple subpixel units 21 and multiple reflective layers 22 enclosing to form a ring-shaped configuration. The multiple pixel structures 20 are assembled on the drive substrate 10 according to the predetermined pattern, which may be designed based on the shape of the pixel structures 20. For example, in the embodiments, the multiple subpixel units 21 and the multiple reflective layers 22 enclose to form a polygonal ring-shaped configuration, such that the subpixel structure 20 is a polygon. In this case, sides with the same side length of adjacent pixel structures 20 may be brought closer together for assembly, thereby arranging the pixel structures 20 more compactly and thus increasing the pixel density.

Specifically, for each adjacent two pixel structures 20, a side of one pixel structure 20 is close to a side of the other pixel structure 20, and the subpixel unit 21 on the side of the one pixel structure 20 is adjacent to the reflective layer 22 of the other pixel structure 20, such that light from the subpixel unit 21 is reflected back into the corresponding pixel structure 20, thereby avoiding light crosstalk between adjacent pixel structures 20, where the light crosstalk could cause color shifts and other issues that affect display quality. It can be understood that, in the pixel structure 20, an outer side of each subpixel unit 21, i.e., a side farthest from the interior, is configured as a corresponding reflective layer 22 of the adjacent pixel structure 20. In this way, when the subpixel unit 21 emits light, the light can be reflected back into the corresponding pixel structure 20 through the reflective layer 22 of the adjacent pixel structure 20, thereby preventing the light from the subpixel unit 21 from entering the adjacent pixel structure 20 and causing color crosstalk.

In the embodiments of the present disclosure, in each pixel structure 20, the multiple subpixel units 21 may be a red subpixel 211, a green subpixel 212, and a blue subpixel 213 to achieve color display. In the embodiments, the pixel structure 20 may be hexagonal in shape. In this case, each three adjacent pixel structures 20 are assembled with a common connecting point, on which three lines are connected and form a “Y” shape. That is, on each of the three lines, a corresponding subpixel unit 21 of one pixel structure 20 and a corresponding reflective layer 22 of another pixel structure are adjacently attached. In other words, on the three lines, three subpixel units 21 are arranged. The subpixel units 21 located on the three lines may have different colors, i.e., the subpixel units 21 located on the three lines may be a red subpixel 211, a green subpixel 212, and a blue subpixel 213, enabling the three subpixel units 21 on the three lines to form another pixel structure 20, thereby further improving the pixel density and pixel resolution.

Of course, in other embodiments, the subpixel units 21 on the three lines may be set as subpixel units 21 with the same light-emitting color, which is advantageous for the fabrication of the subpixel units 21. For example, the subpixel units 21 may specifically be organic light-emitting diodes (OLEDs). In each of the three adjacent pixel structures 20, the subpixel units 21 on the three lines are set to emit the same color, which is more conducive to the vapor deposition process of an organic light-emitting layer 215 and reduces the difficulty of the vapor deposition process.

Referring to FIG. 3, FIG. 3 is a cross-sectional structural schematic view of a pixel structure as shown in FIG. 1 along line A-A according to some embodiments of the present disclosure. In the embodiments, the pixel structure 20 further includes a refractive component 23 and a control component 24 disposed within the ring-shaped configuration. The refractive component 23 includes a first refractive layer 231, a second refractive layer 232, and a third refractive layer 233 stacked in sequence within the ring-shaped configuration to form a transparent region 202 in a region surrounded by the ring-shaped configuration. In a direction parallel to a plane in which the ring-shaped configuration is located, i.e., a direction parallel to the drive substrate 10, the second refractive layer 232 is overlapped with a light-emitting layer 215 of the subpixel unit 21, while the first refractive layer 231 and the third refractive layer 233 are misaligned with the light-emitting layer 215 of the subpixel unit 21. That is, in the direction parallel to the drive substrate 10, a positive projection of the second refractive layer 232 on the subpixel unit 21 is overlapped with the light-emitting layer 215, while a positive projection of each of the first refractive layer 231 and the third refractive layer 233 is not overlapped with the light-emitting layer 215, such that the light from the subpixel unit 21 enters only the second refractive layer 232. That is, in the direction perpendicular to the drive substrate 10, the first refractive layer 231, the second refractive layer 232, and the third refractive layer 233 are stacked in sequence within the ring-shaped configuration. In the direction parallel to the drive substrate 10, the second refractive layer 232 is aligned and overlapped with the light-emitting layer 215 of the subpixel units 21, allowing light from the subpixel units 21 to enter the second refractive layer 232. The first refractive layer 231 and the third refractive layer 233 are misaligned with the light-emitting layer 215 of the subpixel unit 21, i.e., the first refractive layer 231 and the third refractive layer 233 are at different heights from the light-emitting layer 215 of the subpixel unit 21 in the direction perpendicular to the drive substrate 10, such that light from the subpixel unit 21 cannot enter the first refractive layer 231 and the second refractive layer 232. The first refractive layer 231 has a first refractive index n1, the second refractive layer 232 has a second refractive index n2, and the third refractive layer 233 has a third refractive index n3.

The second refractive layer 232 is made of an optical material with a variable refractive index, such as an electro-optic material or a magneto-optic material. The refractive index of electro-optic materials can undergo significant changes under the influence of an external electric field. The electro-optic materials may include lithium niobate crystals, potassium dihydrogen phosphate, and non-ferroelectric oxide photorefractive crystals. Non-ferroelectric oxide photorefractive crystals primarily include bismuth silicate, bismuth germanate, and bismuth titanate. The refractive index of magneto-optical materials can change under the influence of a magnetic field. The magneto-optical materials include antimagnetic materials such as ultra-high-lead glass and arsenic sulfide glass, as well as paramagnetic materials such as yttrium oxide glass and europium selenide crystals. Alternatively, the material of the second refractive layer 232 may be a thermo-optic material, whose refractive index changes with temperature. That is, the second refractive layer 232 may alter its refractive index under the influence of an electric field or magnetic field, or may be controlled by temperature to change its refractive index, depending on the specific material of the second refractive layer 232.

The control component 24 is configured to adjust the refractive index of the second refractive layer 232 such that the light incident from the subpixel unit 21 into the second refractive layer 232 undergoes total internal reflection within the second refractive layer 232 or is emitted from the first refractive layer 231 and the second refractive layer 232. That is, by adjusting the refractive index of the second refractive layer 232 via the control component 24, the second refractive index n2 is made to satisfy a corresponding relationship with the first refractive index n1 and the third refractive index n3, thereby causing the light incident in the second refractive layer 232 from the subpixel unit 21 to undergo total internal reflection within the second refractive layer 232 and unable to enter the first refractive layer 231 and the third refractive layer 233, or allowing the light incident in the second refractive layer 232 from the subpixel unit 21 to enter the first refractive layer 231 and the third refractive layer 233, and then exit after being refracted by the first refractive layer 231 and the third refractive layer 233, respectively.

It can be understood that in the embodiments, the second refractive index n2 of the second refractive layer 232 can be adjusted by the control component 24 to ensure that the second refractive index n2 satisfies a first relationship with the first refractive index n1 and the third refractive index n3, such that the light incident in the second refractive layer 232 from the subpixel unit 21 undergoes total internal reflection within the second refractive layer 232 and does not exit the transparent region 202, thereby enabling the light from the subpixel unit 21 to exit only from the region where the subpixel unit 21 is located (pixel region 201), thus achieving a non-transparent display. Additionally, the control component 24 can adjust the second refractive index n2 to establish a second relationship with the first refractive index n1 and the third refractive index n3, such that the light in the second refractive layer 232 can enter the first refractive layer 231 and the second refractive layer 232, and after refraction by the first refractive layer 231 and the third refractive layer 233, respectively, exit, i.e., the light incident in the second refractive layer 232 from the subpixel unit 21 can exit on both sides of the transparent region 202, thereby achieving transparent display. Therefore, by adjusting the second refractive index n2 of the second refractive layer 232 via the control component 24, the pixel structure 20 can be freely switched between transparent display and non-transparent display, thereby enabling the display panel 100 to be freely switched between transparent display and non-transparent display modes.

As shown in FIG. 3, specifically, the control component 24 includes a first electrode group 241, and the first electrode group 241 includes a first transparent electrode 2411 and a second transparent electrode 2412. The first transparent electrode 2411 is disposed between the first refractive layer 231 and the second refractive layer 232, and the second transparent electrode 2412 is disposed between the second refractive layer 232 and the third refractive layer 233. The first electrode group 241 is configured to generate a corresponding electric field or magnetic field to adjust the second refractive index n2. That is, the second refractive layer 232 is sandwiched between the first transparent electrode 2411 and the second transparent electrode 2412, such that the second refractive layer 232 is disposed with the electric field or magnetic field generated by the first transparent electrode 2411 and the second transparent electrode 2412, thereby changing the second refractive index n2 under the influence of the electric field or magnetic field, causing light incident in the subpixel unit 21 to undergo total internal reflection within the second refractive layer 232 or to be emitted from the first refractive layer 231 and the second refractive layer 232, thereby achieving non-transparent display or transparent display. In this way, the second refractive index n2 can be controlled by the first electrode group 241 to freely switch between non-transparent display and transparent display. Specifically, the non-transparent display of the pixel structure 20 refers to a pixel region display mode, and the transparent display of the pixel structure 20 refers to a transparent display mode.

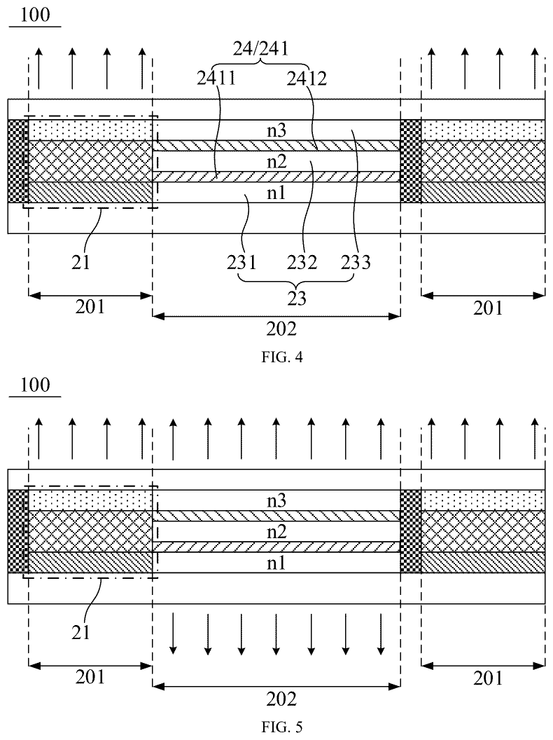

Referring to FIG. 4, FIG. 4 is a schematic view illustrating a state where the pixel structure as shown in FIG. 3 is in a pixel region display mode. In the embodiments, the refractive indices of the first refractive layer 231 and the third refractive layer 233 are the same, i.e., the first refractive index n1 is equal to the third refractive index n3. When the pixel structure 20 switches to the pixel region display mode, the first electrode group 241 adjusts the second refractive index n2 to be greater than the first refractive index n1. Light incident in the second refractive layer 232 from the subpixel units 21 undergoes total internal reflection within the second refractive layer 232, preventing the light from exiting the transparent region 202. Therefore, in the pixel region display mode, light from the subpixel unit 21 only exits from the pixel region 201. That is, in the pixel region display mode, the display region of the display panel 100 is located in the pixel region 201.

It can be understood that in the case where the light in the second refractive layer 232 undergoes total internal reflection in the second refractive layer 232 and does not incident in the first refractive layer 231 and the third refractive layer 233, the relationship between the second refractive index n2 and the first refractive index n1 can be obtained based on the principle of light refraction, thereby determining the range of the second refractive index n2. Therefore, according to the principle of light refraction, when the second refractive index n2 is greater than the first refractive index n1, and the difference between the second refractive index n2 and the first refractive index n1 is not less than a threshold value, the light incident in the second refractive layer 232 from the subpixel unit 21 undergo total internal reflection in the second refractive layer 232, and cannot enter the first refractive layer 231 and the third refractive layer 233. Therefore, the light cannot exit from the transparent region 202, causing the light from the subpixel unit 21 to exit only in the pixel region 201, thereby achieving image display in the pixel region 201.

In the embodiments, the above may be specifically achieved by applying corresponding drive voltages to the first transparent electrode 2411 and the second transparent electrode 2412, thereby generating corresponding drive electric fields between the first transparent electrode 2411 and the second transparent electrode 2412, which causes the second refractive index n2 of the second refractive layer 232 to be greater than the first refractive index n1, thereby controlling the pixel structure 20 to switch to the pixel region display mode.

Referring to FIG. 5, FIG. 5 is a schematic view illustrating a state where the pixel structure as shown in FIG. 3 is in a transparent display mode. Similarly, the refractive indices of the first refractive layer 231 and the third refractive layer 233 are the same, i.e., the first refractive index n1 is equal to the third refractive index n3. In the transparent display mode, the first electrode group 241 adjusts the second refractive index n2 to be less than the first refractive index n1. Light incident in the subpixel unit 21 from the second refractive layer 232 is emitted from the first refractive layer 231 and the third refractive layer 233, respectively. Therefore, in the transparent display mode, the light from the subpixel unit 21 can exit on both sides of the transparent region 202. That is, the transparent region 202 can further serve as a display region, thereby achieving transparent display. It should be noted that the “both sides” of the transparent region 202 here refer to opposite sides of the transparent region 202 in a direction perpendicular to the drive substrate 10.

According to the principle of light refraction, when the second refractive index n2 is less than the first refractive index n1, the light incident in the second refractive layer 232 from the subpixel unit 21 can enter the first refractive layer 231 and the third refractive layer 233 and undergo refraction. After refraction by the first refractive layer 231 and the third refractive layer 233, the light is emitted. Therefore, the light incident in the second refractive layer 232 from the subpixel unit 21 can exit from both sides of the transparent region 202, thereby achieving the transparent display. It can be understood that in the pixel structure 20, lights from the red subpixel 211, green subpixel 212, and blue subpixel 213 enter the second refractive layer 232. Simultaneously, the lights are reflected by the reflective layers 22, causing the three different colored lights to mix within the second refractive layer 232, thereby displaying corresponding colors.

In the embodiments, the above may be specifically achieved by applying corresponding drive voltages to the first transparent electrode 2411 and the second transparent electrode 2412, thereby generating corresponding drive electric fields between the first transparent electrode 2411 and the second transparent electrode 2412, which causes the second refractive index n2 of the second refractive layer 232 to be less than the first refractive index n1, thereby controlling the pixel structure 20 to switch to the transparent display mode.

In the embodiments of the present disclosure, the subpixel unit 21 includes an anode electrode 214, a light-emitting layer 215, and a cathode electrode 216 stacked in sequence along a direction perpendicular to a plane in which the ring-shaped configuration is located. The cathode electrode 216 and/or the anode electrode 214 are transparent electrodes; or, the anode electrode 214 and/or the cathode electrode 216 are reflective electrodes. That is, the cathode electrode 216 may be a transparent electrode, and the anode electrode 214 may be a reflective electrode; or, the cathode electrode 216 may be a reflective electrode, and the anode electrode 214 may be a transparent electrode; or, the cathode electrode 216 and the anode electrode 214 may both be transparent electrodes; or, the cathode electrode 216 and the anode electrode 214 may both be reflective electrodes, which depends on actual display requirements.

For example, in some embodiments, the anode electrode 214 is a reflective electrode, and the cathode electrode 216 is a transparent electrode. In the pixel region display mode of the pixel structure 20, light from the subpixel unit 21 is emitted only from the cathode electrode 216 region, causing the display panel 100 to display an image only on a side where the cathode is located, while the other side remains non-illuminated. In the transparent display mode, the light from the subpixel unit 21 can be emitted from the pixel region 201 on the side where the cathode electrode 216 is located and the transparent region 202, causing the brightness of the display panel 100 on the side where the cathode electrode 216 is located to be greater than that on the other side. In this way, the display panel 100 can achieve dual-sided display and adapt to environments where one side is darker and the other side is brighter, while further being switchable to a single-sided display mode to better protect privacy.

Alternatively, in some embodiments, the cathode electrode 216 and the anode electrode 214 are both transparent electrodes. In the pixel region display mode, light from the subpixel unit 21 can be emitted from both sides of the pixel region 201, enabling the display panel 100 to achieve dual-sided display. In this mode, the display area of the display panel 100 is smaller, and the brightness is lower, making it suitable for darker environments and scenes to enhance visual comfort. In the transparent display mode, light from the subpixel unit 21 can be emitted from both sides of the pixel region 201 and the transparent region 202, i.e., the display region includes the pixel region 201 and the transparent region 202, thereby increasing the display area; further, the light in the second refractive layer 232 can be emitted from the transparent region 202, improving display brightness, which allows the display panel 100 to be used in brighter environments and scenarios to enhance display performance. This configuration enables the display panel 100 to be applicable to a wider range of scenarios.

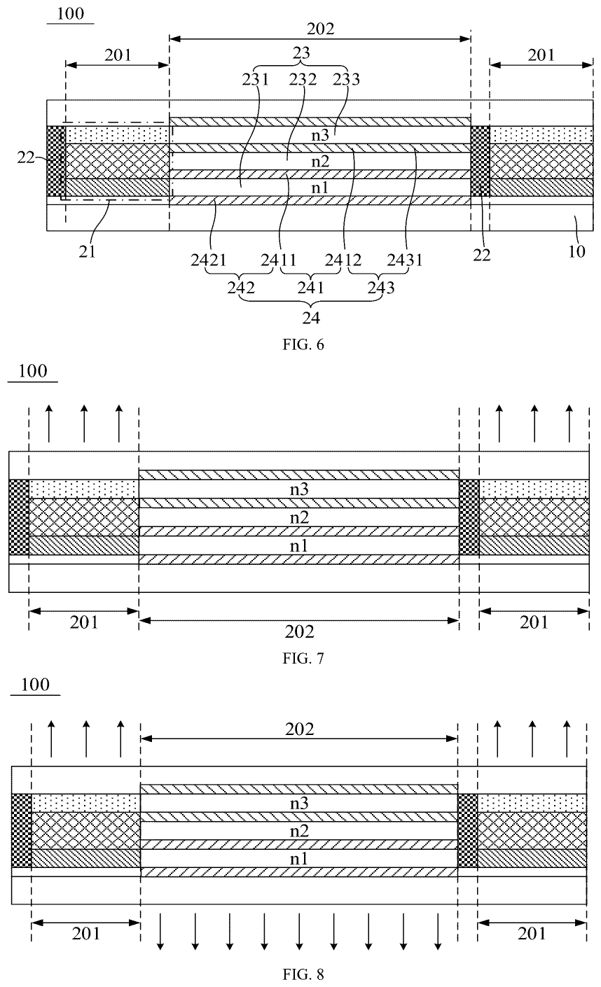

Referring to FIG. 6, FIG. 6 is a cross-sectional structural schematic view of a pixel structure as shown in FIG. 1 along line A-A according to other embodiments of the present disclosure. In the embodiments, the control component 24 includes a first electrode group 241, a second electrode group 242, and a third electrode group 243. The structure and function of the first electrode group 241 are the same as those of the first electrode group 241 in the embodiments shown in FIG. 3, and may achieve the same technical effects. For details, reference may be made to the relevant description above. The second electrode group 242 includes a third transparent electrode 2421 and the first transparent electrode 2411. The third transparent electrode 2421 is disposed on a side of the first refractive layer 231 away from the second refractive layer 232. The second electrode group 242 is configured to generate a corresponding electric field or magnetic field to adjust the first refractive index n1 of the first refractive layer 231; that is, the first transparent electrode 2411 in the first electrode group 241 further serves as one of the electrodes in the second electrode group 242. The third electrode group 243 includes the second transparent electrode 2412 and a fourth transparent electrode 2431, and the fourth transparent electrode 2431 is disposed on a side of the third refractive layer 233 away from the second refractive layer 232. The third electrode group 243 is configured to generate a corresponding electric field or magnetic field to adjust the third refractive index n3; that is, the second transparent electrode 2412 in the first electrode group 241 further serves as one of the electrodes in the third electrode group 243.

It can be understood that the first refractive layer 231 is sandwiched between the first transparent electrode 2411 and the third transparent electrode 2421, such that the first refractive layer 231 can change its first refractive index n1 under the influence of the electric field or magnetic field generated by the first transparent electrode 2411 and the third transparent electrode 2421. The second refractive layer 232 is sandwiched between the first transparent electrode 2411 and the second transparent electrode 2412, such that the second refractive layer 232 can change its second refractive index n2 under the influence of the electric field or magnetic field generated between the first transparent electrode 2411 and the second transparent electrode 2412. The third refractive layer 233 is sandwiched between the second transparent electrode 2412 and the fourth transparent electrode 2431, such that the third refractive layer 233 can change its third refractive index n3 under the influence of the electric field or magnetic field generated between the second transparent electrode 2412 and the fourth transparent electrode 2431. Through the above configuration, the first refractive index n1, the second refractive index n2, and the third refractive index n3 can be adjusted by the first electrode group 241, the second electrode group 242, and the third electrode group 243, respectively, thereby controlling the state of light incident into the second refractive layer 232 from the subpixel unit 21. i.e., total internal reflection occurs within the second refractive layer 232, or being emitted from the first refractive layer 231, or being emitted from the second refractive layer 232, or being emitted from the first refractive layer 231 and the second refractive layer 232. The above design enables the display panel 100 to have more display modes to accommodate a wider range of application scenarios.

It should be noted that in the above embodiments, the control component 24 is required to be insulated from the anode electrode 214 and cathode electrode 216 of the subpixel unit 21, so as to prevent abnormal light emission of the subpixel unit 21 and abnormal second refractive index n2 caused by signal crosstalk, and thus prevent display mode switching failure or damage to the subpixel units 21, etc. Specifically, in the embodiments, the control component 24 and the anode electrode 214 and cathode electrode 216 of the subpixel unit 21 are respectively disposed in different film layers, such that the control component 24 is insulated from the anode electrode 214 and cathode electrode 216 of the subpixel unit 21. This configuration allows the second refractive layer 232 to come into direct contact with the light-emitting layer 215 and also enables the electrodes of the control component 24 to fully cover the second refractive layer 232, which may ensure that all light from the subpixel unit 21 is directed into the second refractive layer 232, preventing light leakage into the first refractive layer 231 and the third refractive layer 233, thereby maintaining the display quality during the pixel region display mode.

Alternatively, referring to FIG. 15, in some embodiments, an insulating layer 25 may be arranged on a side of the subpixel unit 21 adjacent to the ring-shaped interior, i.e., the insulating layer 25 is arranged between the control component 24 and the subpixel unit 21 to insulate the subpixel unit 21 from the control component 24. Alternatively, in some embodiments, an end of the second refractive layer 232 close to the subpixel unit 21 protrudes, along a direction perpendicular to a plane where the second refractive layer 232 is located, towards two sides, thereby insulating the control component 24 from the anode electrode 214 and the cathode electrode 216.

Referring to FIG. 7, FIG. 7 is a schematic view illustrating a state where the pixel structure as shown in FIG. 6 is in a pixel region display mode. Specifically, in the pixel region display mode, the control component 24 adjusts the second refractive index n2 to be greater than the first refractive index n1 and greater than the third refractive index n3, such that the light incident in the subpixel unit 21 into the second refractive layer 232 undergoes total internal reflection within the second refractive layer 232, and not exit from the transparent region 202. The light from the subpixel unit 21 only exit from the pixel region 201, thereby positioning the light-emitting region exclusively within the pixel region 201.

Referring to FIG. 8, FIG. 8 is a schematic view illustrating a state where the pixel structure as shown in FIG. 6 is in a first display mode. In the first display mode, the control component 24 adjusts the first refractive index n1 to be greater than the second refractive index n2, and the second refractive index n2 to be greater than the third refractive index n3, such that the light incident in the second refractive layer 232 from the subpixel unit 21 can enter the first refractive layer 231, and after refraction by the first refractive layer 231, exit outward. The third refractive index n3 of the third refractive layer 233 is less than the second refractive index n2 of the second refractive layer 232, preventing light from entering the third refractive layer 233. Therefore, in this display mode, only one side of the transparent region 202, i.e., the side with the first refractive layer 231, can perform the display function. By configuring the anode electrode 214 and cathode electrode 216, i.e., configuring them to be refractive or transparent, single-sided or double-sided display can be achieved. Specifically, the type of the anode electrode 214 and the cathode electrode 216 (transparent electrode, reflective electrode) may be selected according to actual requirements to meet different usage needs.

Specifically, the correspondence between the drive voltages of the first transparent electrode 2411, the second transparent electrode 2412, the third transparent electrode 2421, and the fourth transparent electrode 2431, and the first refractive index n1, the second refractive index n2, and the third refractive index n3 may be obtained through testing. Based on this correspondence, the first refractive index n1, the second refractive index n2, and the third refractive index n3 can be adjusted by controlling the drive voltages of the first transparent electrode 2411, the second transparent electrode 2412, the third transparent electrode 2421, and the fourth transparent electrode 2431, thereby switching the display panel 100 to different display modes.

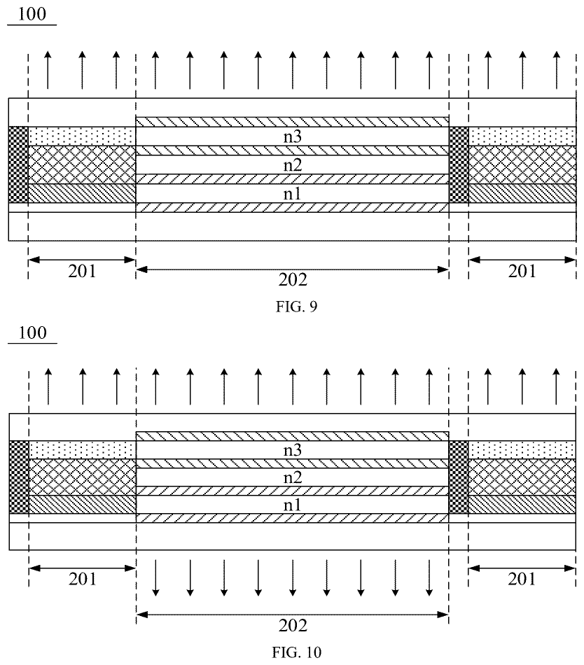

Referring to FIG. 9, FIG. 9 is a schematic view illustrating a state where the pixel structure as shown in FIG. 6 is in a second display mode. In the second display mode, the control component 24 adjusts the first refractive index n1 to be less than the second refractive index n2, and the second refractive index n2 to be less than the third refractive index n3, such that the light incident into the second refractive layer 232 from the subpixel unit 21 can enter the third refractive layer 233, and after refraction by the third refractive layer 233, exit outward. The first refractive index n1 of the first refractive layer 231 is less than the second refractive index n2 of the second refractive layer 232, preventing light from entering the first refractive layer 231. Therefore, in this display mode, only one side of the transparent region 202, i.e., the side with the third refractive layer 233, can perform the display function. By configuring the anode electrode 214 and cathode electrode 216, i.e., configuring them to be refractive or transparent, single-sided or double-sided display can be achieved. Specifically, the type of the anode electrode 214 and the cathode electrode 216 (transparent electrode, reflective electrode) may be selected according to actual requirements to meet different usage needs.

Referring to FIG. 10, FIG. 10 is a schematic view illustrating a state where the pixel structure as shown in FIG. 6 is in a transparent display mode. In the transparent display mode, the control component 24 adjusts the second refractive index n2 to be less than the first refractive index n1, and the second refractive index n2 to be less than the third refractive index n3, such that the light in the second refractive layer 232 can exit through the first refractive layer 231 and the third refractive layer 233. In this display mode, the display region includes the pixel region 201 and the transparent region 202, thereby increasing the area of the display region. Additionally, since the light in the second refractive layer 232 can exit through the transparent region 202, the display brightness is improved, enabling the display panel 100 to be used in brighter environments and scenarios to enhance display performance. This configuration allows the display panel 100 to be applicable to a wider range of scenarios. In this display mode, the viewing angle can be adjusted by adjusting the first refractive index n1 and the third refractive index n3 via the second electrode group 242 and the third electrode group 243, respectively, to meet different viewing angle requirements of the display panel.

In some embodiments, a side of the subpixel unit 21 close to the interior of the ring-shaped configuration is further arranged with an insulating layer to insulate the control component 24 from the anode electrode 214 and the cathode electrode 216, thereby preventing short circuits between the control component 24 and the electrodes of the subpixel unit 21, where the short circuits could cause signal crosstalk and result in abnormal refractive indices of the subpixel unit 21.

Referring again to FIG. 1, in the embodiments, the pixel structure 20 has a polygonal shape, with the subpixel units 21 and the reflective layers 22 enclosing to form a polygonal ring. Each side of the polygonal ring includes one subpixel unit 21 or one reflective layer 22, with the red subpixel 211, the green subpixel 212, and the blue subpixel 213 arranged adjacently in sequence, and the multiple reflective layers 22 arranged adjacently in sequence.

Specifically, each subpixel unit 21 forms one side of the polygonal ring, each reflective layer 22 forms one side of the polygonal ring, and the sides where the red subpixel 211, the green subpixel 212, and the blue subpixel 213 are located are connected, and the sides where the multiple reflective layers 22 are located are connected. In the embodiments, taking the pixel structure 20 as a hexagon as an example, the red subpixel 211, the green subpixel 212, the blue subpixel 213, and the three reflective layers 22 are arranged to form a hexagonal ring, with the transparent region 202 formed inside the hexagonal ring, such that each subpixel unit 21 is adjacent to a corresponding reflective layer 22 on its opposite side, thereby enhancing display brightness. In addition, by virtue of the principle of light reflection, light from the subpixel unit 21 is allowed to mix in the transparent region 202, thereby improving the light mixing effect.

In the embodiments, multiple pixel structures 20 are interconnected to form a honeycomb structure, enhancing the compactness and structural stability between pixel structures 20 while further improving the material utilization efficiency of the subpixel units 21.

Furthermore, in the pixel structure 20, a black matrix BM is arranged between adjacent subpixel units 21, and further between the subpixel unit 21 and its adjacent reflective layer 22, so as to isolate adjacent subpixel units 21 and prevent color crosstalk between them.

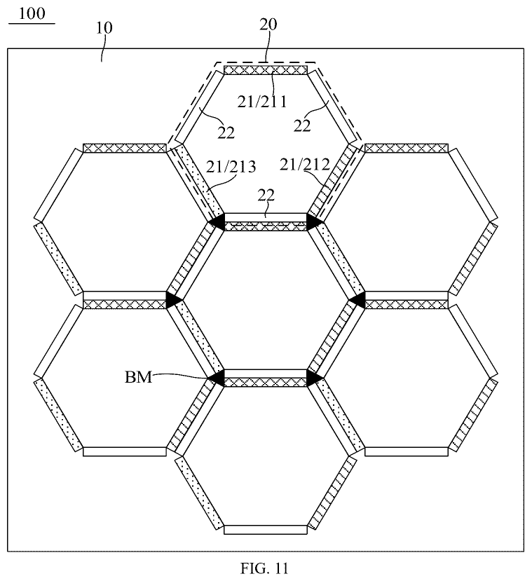

Referring to FIG. 11, FIG. 11 is a plane structural schematic view of a display panel according to Implementation 2 of the present disclosure. Unlike the Implementation 1, in the present embodiments, in the pixel structure 20, adjacent two sides of each subpixel unit 21 are reflective layers 22. That is, the subpixel units 21 and the reflective layers 22 are alternately arranged along the perimeter of the polygon, enabling the light from the subpixel units 21 to mix more effectively in the transparent region 202, thereby improving the uniformity of light mixing and enhancing the display performance of the display panel 100.

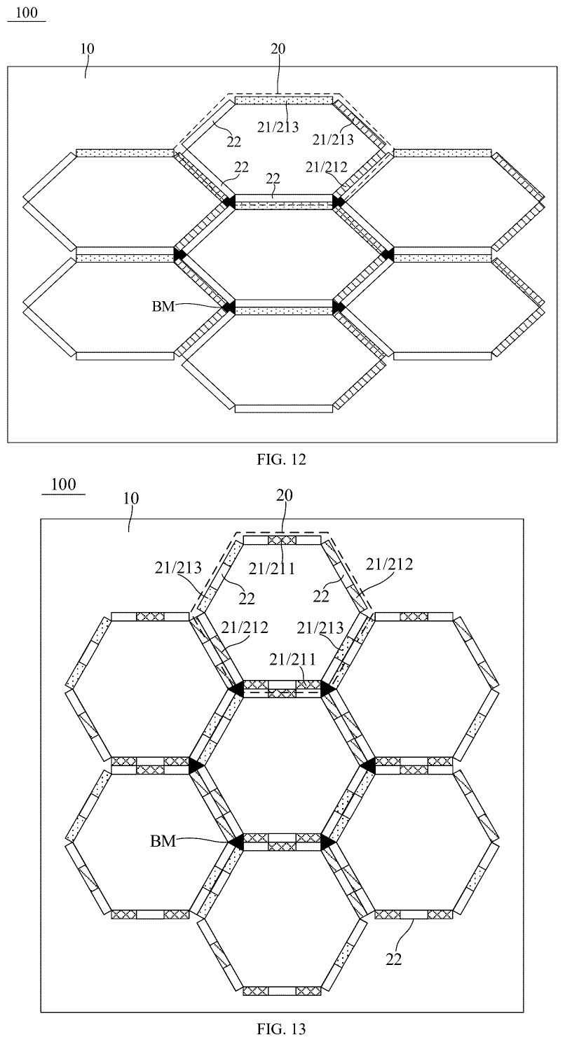

Referring to FIG. 12, FIG. 12 is a plane structural schematic view of a display panel according to Implementation 3 of the present disclosure. Unlike the Implementations 1 and 2, in the present embodiments, the length of the side where the blue subpixel 213 is located in each pixel structure 20 is greater than the length of the side where the red subpixel 211 is located, and further greater than the length of the side where the green subpixel 212 is located. That is, in a direction parallel to the drive substrate 10, the extension length of the blue subpixel 213 is greater than the extension length of the red subpixel 211 and also greater than the extension length of the green subpixel 212.

In the embodiments, the subpixel unit 21 is an OLED light-emitting device. The light-emitting efficiency of organic light-emitting materials of different colors is different, where red typically has the highest light-emitting efficiency, followed by green, and blue has the lowest light-emitting efficiency. To improve the light-emitting efficiency of the blue subpixel 213 and extend its service life, in the embodiments, the extension length of the blue subpixel 213 is made greater than the extension lengths of the red subpixel 211 and the green subpixel 212, which may ensure that the light-emitting efficiencies of the subpixel units 21 of different colors are more balanced, and the aging rates of the subpixel units 21 of different colors are also more balanced, thereby preventing issues such as color deviation in the display panel 100 as the usage time increases. Furthermore, the extension length of the reflective layer 22 on the opposite side of the blue subpixel 213 is the same as the extension length of the blue subpixel 213, thereby increasing the reflective area, thereby improving reflective efficiency and further enhancing display brightness.

Referring to FIG. 13, FIG. 13 is a plane structural schematic view of a display panel according to Implementation 4 of the present disclosure. Unlike the above Implementations, in the present embodiments, each side of the polygonal ring includes at least one subpixel unit 21 and at least one reflective layer 22, with the at least one subpixel unit 21 and at least one reflective layer 22 alternately arranged along the perimeter of the ring. Additionally, the emission colors of the subpixel units 21 on the same side of the polygonal ring are the same, while different from those of the subpixel units 21 on the adjacent sides.

Through the above configuration, the pixel structure 20 includes multiple subpixel units 21 of the same color, and the multiple subpixel units 21 of the same color may be distributed on at least two non-adjacent sides of the polygon, with at least one subpixel unit 21 and at least one reflective layer 22 present on each side. This design may result in a more balanced distribution of subpixel units 21 and reflective layers 22, further improving light mixing uniformity. Taking a hexagonal pixel structure 20 as an example, in the embodiments, multiple subpixel units 21 of the same color are distributed on two opposite sides of the polygon. One side includes one subpixel unit 21 and two reflective layers 22, with the subpixel unit 21 disposed between the two reflective layers 22; while the opposite side includes two subpixel units 21 and one reflective layer 22, with the reflective layer 22 disposed between the two subpixels 21. This arrangement may ensure that the subpixel units 21 and reflective layers 22 on the two opposite sides are offset, such that each subpixel unit 21 is aligned with a corresponding reflective layer 22 at its opposite position, thereby improving reflective efficiency.

Furthermore, in the hexagonal pixel structure 20, the number of subpixel units 21 on a side is different from the number of subpixel units 21 on an adjacent side. For example, one side may have one subpixel unit 21 and two reflective layers 22, while the adjacent side has two subpixel units 21 and one reflective layer 22. This arrangement may ensure that the subpixel units 21 and reflective layers 22 are distributed more evenly across the polygonal pixel structure 20, thereby further improving the light mixing uniformity of the transparent region 202.

In the embodiments, the above configuration increases the number of subpixel units 21, which not only improves the uniformity of light mixing but also enhances the display brightness of the pixel structure 20, thereby improving the display brightness and display quality of the display panel 100.

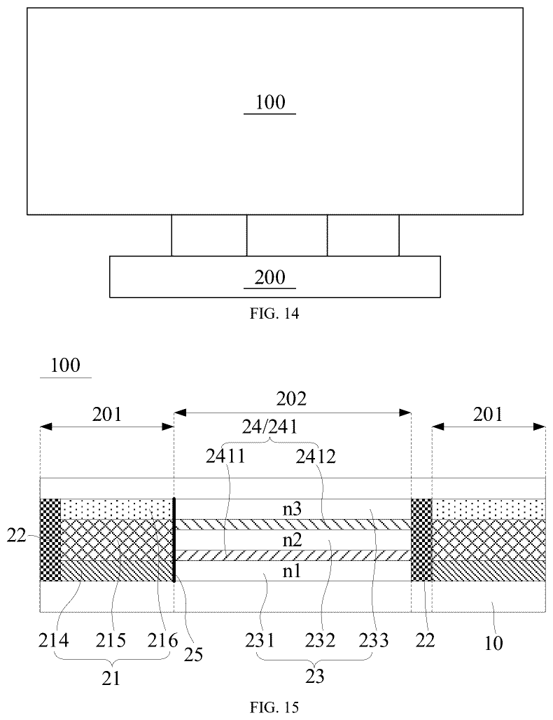

Referring to FIG. 14, FIG. 14 is a structural schematic view of a display device according to some embodiments of the present disclosure. In the embodiments, a display device is provided, which includes the display panel 100 provided in the above embodiments. The pixel structure 20 of the display panel 100 is configured as described above and may achieve the same technical effects, not only increasing the area of the transparent region 202, improving transparency during transparent display, and enhancing the transparent display effect, but also enabling the display device to have multiple display modes and switch between corresponding display modes according to different usage scenarios, thereby meeting multi-scenario display requirements.

Furthermore, the display device may further include a control module 200, which is electrically connected to the control component 24 in the display panel 100 to provide the control component 24 with corresponding drive voltages, thereby controlling the first refractive index n1 of the first refractive layer 231, the second refractive index n2 of the second refractive layer 232, and the third refractive index n3 of the third refractive layer 233 in the pixel structure 20, thus controlling the display panel 100 to switch to the corresponding display mode.

The beneficial effects of the present disclosure: Distinct from existing technologies, the present disclosure provides a pixel structure and a display panel. The pixel structure is applied to a display panel and includes multiple subpixel units and multiple reflective layers, with the multiple subpixel units and multiple reflective layers arranged in a ring-shaped configuration. By stacking a first refractive layer, a second refractive layer, and a third refractive layer within the ring-shaped configuration, a transparent region is formed in a region enclosed by the ring-shaped configuration. This allows light from each subpixel unit to enter the transparent region, where it is mixed by the reflective action of the reflective layers. After mixing, the light is refracted by the three refractive layers and emitted from both sides of the transparent region, enabling the pixel structure to achieve transparent display in the transparent region, thereby effectively improving the display transparency of the pixel structure while maintaining display brightness. Furthermore, in a direction parallel to a plane in which the ring-shaped configuration is located, i.e., parallel to the light-emitting surface, the second refractive layer is overlapped with the subpixel units, and the first refractive layer and the third refractive layer are misaligned with the subpixel units, such that light from the subpixel units is incident only onto the second refractive layer. Additionally, by including a control component in the pixel structure to adjust the refractive index (second refractive index) of the second refractive layer, the refractive index of the second refractive layer can be adjusted to cause light within the second refractive layer to undergo total internal reflection without exiting, thereby ensuring that light from the subpixel units can only exit from the region where the subpixel units are located (pixel region) and cannot exit from the transparent region, thereby achieving a non-transparent display; or, by adjusting the second refractive index, light in the second refractive layer can be emitted separately from the first refractive layer and the third refractive layer, i.e., light from the subpixel unit can be emitted from the transparent region, thereby achieving a transparent display. That is, the pixel structure provided by the present disclosure can control the refractive index of the second refractive layer in the transparent region through the control component, thereby controlling whether the light entering the second refractive layer undergoes total internal reflection within the second refractive layer or is emitted separately from the first refractive layer and the third refractive layer. In this way, the pixel structure can freely switch between non-transparent display and transparent display by adjusting the second refractive index through the control component.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A pixel structure, comprising:
a plurality of subpixel units and a plurality of reflective layers; wherein the plurality of subpixel units and the plurality of reflective layers enclose to form a ring-shaped configuration; and
a refractive component and a control component, that are disposed within the ring-shaped configuration;
wherein the refractive component comprises a first refractive layer, a second refractive layer, and a third refractive layer stacked in sequence; in a direction parallel to a plane in which the ring-shaped configuration is located, the second refractive layer is overlapped with a light-emitting layer of the subpixel unit, and the first refractive layer and the third refractive layer are misaligned with the light-emitting layer of the subpixel unit; light incident from the subpixel unit is configured to only enter the second refractive layer;
wherein the control component is configured to adjust a refractive index of the second refractive layer; in response to adjustment of the refractive index of the second refractive layer, the light incident from the subpixel unit into the second refractive layer is capable of switching between undergoing total internal reflection within the second refractive layer and being emitted from at least one of the first refractive layer and the second refractive layer.

2. The pixel structure according to claim 1, wherein the first refractive layer has a first refractive index, the refractive index of the second refractive layer is a second refractive index, and the third refractive layer has a third refractive index;
the control component comprises a first electrode group, and the first electrode group comprises a first transparent electrode and a second transparent electrode; the first transparent electrode is disposed between the first refractive layer and the second refractive layer, and the second transparent electrode is disposed between the second refractive layer and the third refractive layer; the first electrode group is configured to generate a corresponding electric field or magnetic field to adjust the second refractive index.

3. The pixel structure according to claim 2, wherein the first refractive index is equal to the third refractive index;
in a pixel region display mode, the first electrode group is configured to adjust the second refractive index to be greater than the first refractive index, and the light in the second refractive layer is caused to undergo the total internal reflection within the second refractive layer;
in a transparent display mode, the first electrode group is configured to adjust the second refractive index to be less than the first refractive index, and the light in the second refractive layer is caused to be emitted from the first refractive layer and the third refractive layer, respectively.

4. The pixel structure according to claim 2, wherein the control component further comprises a second electrode group and a third electrode group;
the second electrode group comprises a third transparent electrode and the first transparent electrode, and the third transparent electrode is disposed on a side of the first refractive layer away from the second refractive layer; the second electrode group is configured to generate a corresponding electric field or magnetic field to adjust the first refractive index of the first refractive layer;
the third electrode group comprises the second transparent electrode and a fourth transparent electrode, and the fourth transparent electrode is disposed on a side of the third refractive layer away from the second refractive layer; the third electrode group is configured to generate a corresponding electric field or magnetic field to adjust the third refractive index.

5. The pixel structure according to claim 4, wherein
in a first display mode, the control component is configured to adjust the first refractive index to be greater than the second refractive index, and the second refractive index to be greater than the third refractive index; the light incident in the second refractive layer is caused to be emitted from the first refractive layer;
in a second display mode, the control component is configured to adjust the first refractive index to be less than the second refractive index, and the second refractive index to be less than the third refractive index; the light incident in the second refractive layer is caused to be emitted from the third refractive layer;
in a transparent display mode, the control component is configured to adjust the second refractive index to be less than the first refractive index, and the second refractive index to be less than the third refractive index; the light in the second refractive layer is caused to be emitted from the first refractive layer and the third refractive layer, respectively.

6. The pixel structure according to claim 3, wherein each subpixel unit comprises an anode electrode, a light-emitting layer, and a cathode electrode stacked in sequence along a direction perpendicular to the plane in which the ring-shaped configuration is located;
the cathode electrode is a transparent electrode, and the anode electrode is a reflective electrode; or, the cathode electrode is a reflective electrode, and the anode electrode is a transparent electrode; or, the cathode electrode and the anode electrode are both transparent electrodes; or, the cathode electrode and the anode electrode are both reflective electrodes;
the control component is insulated from the anode electrode and the cathode electrode.

7. The pixel structure according to claim 5, wherein each subpixel unit comprises an anode electrode, a light-emitting layer, and a cathode electrode stacked in sequence along a direction perpendicular to the plane in which the ring-shaped configuration is located;
the cathode electrode is a transparent electrode, and the anode electrode is a reflective electrode; or, the cathode electrode is a reflective electrode, and the anode electrode is a transparent electrode; or, the cathode electrode and the anode electrode are both transparent electrodes; or, the cathode electrode and the anode electrode are both reflective electrodes;
the control component is insulated from the anode electrode and the cathode electrode.

8. The pixel structure according to claim 1, wherein the plurality of subpixel units are a red subpixel, a green subpixel, and a blue subpixel; the red subpixel, the green subpixel, the blue subpixel, and the plurality of reflective layers enclose to form a polygonal ring.

9. The pixel structure according to claim 8, wherein on each side of the polygonal ring, a corresponding one subpixel unit or a corresponding one reflective layer is arranged; the red subpixel, the green subpixel, and the blue subpixel are arranged adjacent to each other in sequence, and the plurality of reflective layers are arranged adjacent to each other in sequence.

10. The pixel structure according to claim 8, wherein on each side of the polygonal ring, at least one corresponding subpixel unit and at least one corresponding reflective layer are arranged; the plurality of subpixel units and the plurality of reflective layers alternately arranged along a perimeter of the polygonal ring, to form a closed chain structure comprising repetition units, where each repetition unit is formed by a corresponding subpixel unit and a reflective layer; the at least one corresponding subpixel unit on the side of the polygonal ring has a same emission color, and the emission color is different from an emission color of another at least one corresponding subpixel unit on an adjacent side of the polygonal ring.

11. The pixel structure according to claim 10, wherein for each adjacent two sides of the polygonal ring, the adjacent two sides is a first side and a second side, a number of the at least one corresponding subpixel unit on the first side is different from a number of the at least one corresponding subpixel unit on the second side.

12. The pixel structure according to claim 8, wherein a length of a side where the blue subpixel is located of the polygonal ring is greater than a length of another side where the red subpixel is located of the polygonal ring and further greater than a length of a side where the green subpixel is located of the polygonal ring.

13. The pixel structure according to claim 8, wherein on each side of the polygonal ring, a corresponding one subpixel unit or a corresponding one reflective layer is arranged; on adjacent sides of each of the plurality of subpixels, corresponding two reflective layer are arranged.

14. The pixel structure according to claim 1, wherein an insulating layer is arranged between the control component and the plurality of subpixel units to insulate the plurality of subpixel units from the control component.

15. The pixel structure according to claim 1, wherein an end of the second refractive layer close to a subpixel unit among the plurality of subpixel units protrudes, along a direction perpendicular to the plane in which the ring-shaped configuration is located, towards two sides, for insulating the control component from the subpixel unit.

16. A display panel, comprising a drive substrate and a plurality of pixel structures disposed on the drive substrate;
wherein for each of the plurality of pixel structures, the pixel structure comprises:
a plurality of subpixel units and a plurality of reflective layers; wherein the plurality of subpixel units and the plurality of reflective layers enclose to form a ring-shaped configuration; and
a refractive component and a control component, that are disposed within the ring-shaped configuration;
wherein the refractive component comprises a first refractive layer, a second refractive layer, and a third refractive layer stacked in sequence; in a direction parallel to a plane in which the ring-shaped configuration is located, the second refractive layer is overlapped with a light-emitting layer of the subpixel unit, and the first refractive layer and the third refractive layer are misaligned with the light-emitting layer of the subpixel unit; light incident from the subpixel unit is configured to only enter the second refractive layer;
wherein the control component is configured to adjust a refractive index of the second refractive layer; in response to adjustment of the refractive index of the second refractive layer, the light incident from the subpixel unit into the second refractive layer is capable of switching between undergoing total internal reflection within the second refractive layer and being emitted from the first refractive layer and the second refractive layer;
wherein the plurality of pixel structures are distributed according to a predetermined pattern; for each adjacent two pixel structures among the plurality of pixel structures, the adjacent two pixel structures are a first pixel structure and a second pixel structure, a side of the first pixel structure is close to a side of the second pixel structure, and a corresponding subpixel unit on the side of the first pixel structure is adjacent to a corresponding reflective layer of the second pixel structure; the light incident from each subpixel unit is configured to be reflected back into a corresponding pixel structure.

17. The display panel according to claim 16, wherein the first refractive layer has a first refractive index, the refractive index of the second refractive layer is a second refractive index, and the third refractive layer has a third refractive index;
the control component comprises a first electrode group, and the first electrode group comprises a first transparent electrode and a second transparent electrode; the first transparent electrode is disposed between the first refractive layer and the second refractive layer, and the second transparent electrode is disposed between the second refractive layer and the third refractive layer; the first electrode group is configured to generate a corresponding electric field or magnetic field to adjust the second refractive index.

18. The display panel according to claim 17, wherein the first refractive index is equal to the third refractive index;
in a pixel region display mode, the first electrode group is configured to adjust the second refractive index to be greater than the first refractive index, and the light in the second refractive layer is caused to undergo the total internal reflection within the second refractive layer;
in a transparent display mode, the first electrode group is configured to adjust the second refractive index to be less than the first refractive index, and the light in the second refractive layer is caused to be emitted from the first refractive layer and the third refractive layer, respectively.

19. A display device, comprising the display panel according to claim 16 and a control module;
wherein the control module is electrically connected to the control component in the display panel to provide the control component with corresponding drive voltages.

20. A pixel structure, comprising:
a plurality of subpixel units and a plurality of reflective layers; wherein the plurality of subpixel units and the plurality of reflective layers enclose to form a ring-shaped configuration; and
a refractive component, disposed within the ring-shaped configuration;
wherein the pixel structure is configured to be spliced with another pixel structure, and the other pixel structure has a same structure as the pixel structure; in a spliced state, the pixel structure shares a common side with the other pixel structure, where a corresponding subpixel unit of the pixel structure is attached to a corresponding reflective layer of the other pixel structure, or a corresponding subpixel unit of the other pixel structure is attached to a corresponding reflective layer of the pixel structure;
wherein the refractive component comprises a first refractive layer, a second refractive layer, and a third refractive layer stacked in sequence; in a direction parallel to a plane in which the ring-shaped configuration is located, the second refractive layer is overlapped with a light-emitting layer of the subpixel unit, and the first refractive layer and the third refractive layer are misaligned with the light-emitting layer of the subpixel unit; light incident from the subpixel unit is configured to only enter the second refractive layer;
wherein in response to a refractive index of the second refractive layer being changed, the pixel structure is configured to switch between a first display mode and a second display mode;
in the first display mode, the light in the second refractive layer is caused to undergo total internal reflection within the second refractive layer and be emitted from neither of the first refractive layer and the third refractive layer;
in the second display mode, the light in the second refractive layer is caused to be emitted from at least one of the first refractive layer and the third refractive layer.
